(19) United States
(12) Patent Application Publication
(10) Pub. No.: US 2017/0299666 A1
(43) Pub. Date: Oct. 19, 2017

(54) Rapid Magnetic Hotspot Detector

(71) Applicant: HALLIBURTON ENERGY SERVICES, INC., Houston, TX (US)

(72) Inventor: Percival Frederick WILLIAMS, Cheltenham (GB)

(21) Appl. No.: 15/518,074

(22) PCT Filed: Nov. 17, 2014
(86) PCT No.: PCT/US2014/065895

§ 371 Date: Apr. 10, 2017

(51) Int. Cl. G01R 33/04; G01N 27/90; G01R 33/12; G01V 3/26

(52) U.S. Cl. CPC G01R 33/04; G01V 3/26; G01N 27/9033; G01R 33/12

(57) ABSTRACT

A magnetic hotspot detector is capable of locating magnetic hotspots in tubulars, such as tubulars for use downhole. A sensor array can include multiple sets of differential fluxgate magnetometers, each set comprising two non-differential fluxgate magnetometers arranged across the diameter of a tubular to be measured. As the tubular passes through the sensor array, fluctuations in magnetic field due to the movement of the tubular through the sensor array are measured to provide indication of the location of magnetic hotspots. To locate hotspots, a tubular can be passed through the sensor array or the sensor array can pass over the tubular.

### TECHNICAL FIELD

The present disclosure relates to wellbore equipment generally and more specifically to detecting magnetic hot spots in wellbore tubulars.

### BACKGROUND

In oilfield operations, tubulars carry sensitive electronic equipment into downhole environments. Some electronic equipment may be negatively affected by magnetic hotspots in the tubulars. For example, positioning sensors can be used downhole to measure the position or orientation of a tool downhole. These positioning sensors can include multiple accelerometers and multiple magnetic sensors to measure the angle and position of the tool. If there is any magnetic interference from the tubulars, errors may be induced in the measurements. Magnetic hotspots in tubulars can result in magnetic interference that induces errors in such measurements.

### BRIEF DESCRIPTION OF THE DRAWINGS

The specification makes reference to the following appended figures, in which use of like reference numerals in different figures is intended to illustrate like or analogous components

FIG. 1 is an axonometric projection of a hotspot detection system according to certain features of the disclosed subject matter.

FIG. 2 is a front view of the hotspot detection system of FIG. 1 according to certain features of the disclosed subject matter.

FIG. 3 is an axonometric projection of a hotspot detection system with offset sets of sensors according to certain features of the disclosed subject matter.

FIG. 4 is a front view of the hotspot detection system of FIG. 3 according to certain features of the disclosed subject matter.

FIG. 5 is a schematic view of a differential fluxgate magnetometer created from a single non-differential fluxgate magnetometer according to certain features of the disclosed subject matter.

FIG. 6 is a schematic view of a differential fluxgate magnetometer created from two non-differential fluxgate magnetometers arranged in a parallel arrangement according to certain features of the disclosed subject matter.

FIG. 7 is a schematic view of a differential fluxgate magnetometer created from two non-differential fluxgate magnetometers arranged in a parallel and coincident arrangement according to certain features of the disclosed subject matter.

FIG. 8 is a schematic view of a set of differential fluxgate magnetometers created from two non-differential fluxgate magnetometers arranged in a parallel and coincident arrangement according to certain features of the disclosed subject matter.

FIG. 9 is a schematic view of a sensor array including four sets of differential fluxgate magnetometers created from eight non-differential fluxgate magnetometers according to certain features of the disclosed subject matter.

FIG. 10 is a block diagram of a system for analyzing signals from one or more differential magnetic sensors according to certain features of the disclosed subject matter.

FIG. 11 is a flowchart of a process for detecting magnetic hotpots in a tubular according to certain features of the disclosed subject matter.

FIG. 12 is a flowchart of a process for detecting magnetic hotpots in a tubular according to certain features of the disclosed subject matter.

FIG. 13 is a schematic view of an indication circuit including signal processing paths for a hotspot detection system according to certain features of the disclosed subject matter.

### DETAILED DESCRIPTION

Certain aspects and features of the present disclosure relate to magnetic hotspot detector capable of locating magnetic hotspots in tubulars, such as tubulars for use downhole. The magnetic hotspot detector can include a sensor array made of multiple sets of differential fluxgate magnetometers. A differential fluxgate magnetometer can be comprised of two non-differential fluxgate magnetometers arranged parallel and collinear across the diameter of a tubular to be measured. As the tubular passes through the sensor array, fluctuations in magnetic field due to the movement of the tubular through the sensor array are measured to provide indication of the location of magnetic hotspots. Because the non-differential fluxgate magnetometers are configured together to be a differential fluxgate magnetometer, measurements of ambient magnetic fields (e.g., the Earth's magnetic field) are substantially zero. To locate hotspots, a tubular can be at least partially passed through the sensor array and/or the sensor array can at least partially pass over the tubular.

Locating hotspots on a tubular can occur prior to the tubular being run downhole. Any hotspots on the tubular can be treated, such as by demagnetization. In some embodiments, the hotspots on the tubular can be recorded and accounted for at a later time. When placed downhole, a tubular for which the hotspots have been detected can allow magnetically steered tools or magnetic equipment to be used with more accuracy.

Magnetic hotspots in supposedly non-magnetic material (e.g., tubulars for use downhole) can affect the measurements taken by magnetic sensors, such as fluxgate magnetometers or other magnetometers used in downhole tools, such as survey tools. These magnetic hotspots can cause errors, such as errors in magnetic steering and highside angles. If detected prior to deployment, a magnetic hotspot can be eliminated.

A downhole tubular, such as a pressure case, can be manufactured from non-magnetic stainless steel. Examples of ways magnetic hotspots can occur include a localized metallurgic deviation or as a result of contamination during use. Additionally, magnetic swarf from torqueing tools can become embedded in the surface of the tubular or other enclosure. Magnetic hotspots include areas of the tubular that are actually magnetized, as well as areas that are capable of being magnetized. A magnetic hotspot can be an area of the tubular that is magnetically permeable, and can be capable of deviating, focusing or attenuating the earth's magnetic field, thus having the potential to induce errors as described above.

In one embodiment, the magnetic hotspot detector can include an integrating fluxmeter. The tubular to be measured can be drawn through a search coil and the integrating fluxmeter can give an indication of change of flux. The integrating fluxmeter can detect dipoles orientated along the long axis of the tubular, but may not detect radially oriented dipoles. Additionally, the integrating fluxmeter may not detect non-magnetized magnetic hotspots (e.g., hotspots with the potential to be magnetized).

In another embodiment, the magnetic hotspot detector can include a single fluxgate magnetometer. A fluxgate (e.g., of the linear type) can include two coils, each having a start and a finish. The start of the first and second coils can be energized while changes in magnetic flux can be measured at a connection joining the finish of the first coil with the finish of the second coil. The fluxgate magnetometer may have a small area of sensitivity, thus the tubular may be drawn past the fluxgate magnetometer multiple times, rotating the tubular with respect to the fluxgate magnetometer with each pass. Sensitivity can be increased by backing off the external field and increasing the gain of the fluxgate magnetometer. As described above, other types of fluxgates (e.g., a torroidal fluxgate) can be used with appropriate adjustment.

In another embodiment, the magnetic hotspot detector can include a single differential fluxgate magnetometer. The differential fluxgate magnetometer can include a pair of coils (e.g., matched coils) that are connected start to finish (e.g., as opposed to finish to finish or start to start, as in a non-differential fluxgate magnetometer). Each of the pair of coils experience a different flux. The resulting signal from this is taken from the connection between the start and finish of the coils. The differential fluxgate magnetometer can be insensitive to changes in the ambient magnetic field, but highly sensitive to the presence of small, local dipoles.

In some embodiments, multiple non-differential fluxgate magnetometers can be combined to create a multi-fluxgate differential magnetometer. As described herein, a linear type non-differential fluxgate magnetometer is used. Other types of fluxgate magnetometers, such as torroidal type fluxgate magnetometers, can be used with appropriate adjustment (e.g., by splitting the energization winding of the torroidal type fluxgate magnetometer into two, in anti-phase).

The finish of a first non-differential fluxgate magnetometer can be coupled to the start of a first coil of a second non-differential fluxgate magnetometer. The two fluxgate magnetometers can be energized through a start of the first non-differential fluxgate magnetometer and the finish of the second fluxgate magnetometer. The second coil of the first non-differential fluxgate magnetometer and the first coil of the second non-differential fluxgate magnetometer can experience a different flux. The resulting signal can be taken from the connection between the finish of the first non-differential fluxgate magnetometer and the start of the first coil of the second non-differential fluxgate magnetometer. The distance between the energized coils of the two non-differential fluxgate magnetometers determines the sensitivity. At a large distance, any change in the gradient of the ambient field will be read by the multi-fluxgate differential magnetometer. At a very small distance, the differential effect will be reduced.

The non-differential fluxgate magnetometers can be arranged in parallel. In some embodiments, the non-differential fluxgate magnetometers are arranged in parallel and collinear, with the finish of the first non-differential fluxgate magnetometer positioned adjacent to the finish of the second non-differential fluxgate magnetometer, with a gap between. In some embodiments, a material to be measured (e.g., a tubular) can be moved through the gap to be measured.

In some embodiments, two differential fluxgates can be created using two non-differential fluxgates wired together. Energization can be provided to the finish ends of the coils of both non-differential fluxgates. A first output can be taken on a connection connecting the start of the first coil of the first non-differential fluxgate to the start of the first coil of the second non-differential fluxgate. A second output can be taken on a connection connecting the start of the second coil of the first non-differential fluxgate to the start of the second coil of the second non-differential fluxgate. The use of both coils of each of a pair of standard fluxgates to create two differential fluxgates enables sensing (e.g., flux detection) over a wide area.

In an embodiment, multiple differential fluxgates can be mounted in a circle through which a tubular can be passed. In some embodiments, eight non-differential fluxgates can be arranged in the circle. The non-differential fluxgates can be connected together to create four pairs of differential fluxgates. Each pair of differential fluxgates can consist of the corresponding coils of two non-differential fluxgates positioned opposite one another along a diameter of the circle. The corresponding coils can be wired together, as described above, to create two differential fluxgates from the two non-differential fluxgates. Other numbers of fluxgates can be used.

In some embodiments, each fluxgate is positioned very close to the object to be sensed, such as within 10 mm, within 5 mm, within 3.5 mm, or at about 3.1 mm distance between the fluxgate and the material to be sensed (e.g., a tubular). When the fluxgates are arranged in a circular formation, the circle of fluxgates can have an inner diameter that is larger than the outer diameter of the tubular by approximately 20 mm or less, 10 mm or less, 7 mm or less, or about 6.2 mm.

The tubular can be passed through the circle of fluxgates a single time. In some embodiments, the tubular can be passed through the circle of fluxgates a first time, rotated, then passed through the circle of fluxgates a second time. Additional rotations and passes can be used. In some embodiments, the tubular can be rotated between 10° and 15°. In some embodiments, the tubular can be rotated approximately 12°. In some embodiments, the circle of fluxgates can move with respect to the tubular in one or more of an axial direction along the tubular and a rotation around the tubular.

In some embodiments, a second circle of fluxgates can be positioned axially offset from the first circle of fluxgates. The second circle of fluxgates can be rotationally offset with respect to the first circle of fluxgates to provide additional sensing coverage. For example, the second circle of fluxgates can be rotationally offset by between 20° and 25°. In another example, the second circle of fluxgates can be rotationally offset by approximately 22.5°.

In some embodiments, signals from the fluxgates can be rectified. In some embodiments, signals from the fluxgates can be demodulated, such as through phase sensitive demodulator circuits. In some embodiments, the signals from the fluxgates can be offset using offset circuitry. In some embodiments, a single transformer can power multiple fluxgates. In some embodiments, each fluxgate or each differential fluxgate can be powered by a transformer.

In some embodiments, the output of a differential fluxgate can be passed through a low pass filter (e.g., a resistor-capacitor low pas filter). The filtered signal can pass through an absolute value circuit. An absolute value circuit can ensure that even when negative flux is detected, a positive signal is produced, which can avoid non-detection when two hotspots of opposite polarity are presented to two sensors simultaneously.

The outputs of the absolute value circuits from each fluxgate can be fed into a summing circuit. The summing circuit can include a charge amplifier, which can make scan speed less critical.

The summed signal can be passed to two comparators, one comparator having a negative threshold and the other comparator having a positive threshold. Each comparator can drive an interface, such as a light emitting diode (LED). Whenever one or more fluxgates detect a sufficiently high magnetic flux (e.g., from a hotspot in a tubular passed through the circle of fluxgates), one of the comparators can present an indication, such as by lighting an LED. Other indications can be used, such as mechanical indications or computer indications (e.g., sending a signal to a computer system). The comparators can be calibrated to define the threshold at which point indication is desired. For example, the comparators can be calibrated to provide an indication upon sensing a hotspot causing a change of 50 nanoTesla or more in the XY plane (e.g., the plane orthogonal to the long axis of the tubular). Other calibration thresholds can be used. In some embodiments, adjusting a calibration resistor in the comparator circuit to calibrate the sensors can be desirable over adjusting other components of the system.

In some embodiments, calibration can be achieved by first degaussing the pressure case, then incrementally magnetizing a hotspot to produce a change of 50 nanoTesla in the XY plane as detected by a fluxgate within the tubular. The system can then be calibrated by adjusting components (e.g., a calibration resistor) until an indication is provided when the hotspot is moved past the hotspot detector (e.g., circle of fluxgates).

In some embodiments, the detection of hotspots can be automated, by automatically passing one or more tubulars through the hotspot detector. In such automated systems, whenever a hotspot is detected, an indication can be made to record when or where the hotspot was detected. In an embodiment, whenever a hotspot is detected, the system can cause an inking apparatus to deploy ink on the tubular at or near the location of the hotspot.

In some embodiments, prior to being passed through the hotspot detector, the tubular is passed through a magnetizing coil. The magnetizing coil can magnetize hotpots in the tubular in order to make them easier to detect by the hotspot detector.

In some embodiments, the tubular can be passed through a demagnetizing coil (e.g., electromagnetic degausser) to demagnetize any hotpots. In some embodiments, hotspots can be caused by contamination, and the hotpots can be eliminated or reduced by cleaning the tubular to remove the contaminants.

In some embodiments, a method of using the hotspot detector includes performing a first hotspot detection on the tubular as initially received, magnetizing the tubular to activate latent hotspots, performing a second hotspot detection on the magnetized tubular, demagnetizing the tubular, and performing a third hotspot detection on the demagnetized tubular. In some embodiments, magnetization and demagnetization can be performed using the same coil, where magnetization is performed using a direct current (DC) and demagnetization is performed using an alternating current (AC). During demagnetization, the tubular can be drawn through a coil provided with AC. In some embodiments, in order to avoid a memory effect, a tubular can be held within a coil provided with AC while the AC is gradually reduced in amplitude.

In some embodiments, output signals from each differential fluxgate can be provided to a computer for measurement or further processing. In some embodiments, the computer can be programmed to determine whether the detected magnetic flux surpasses a threshold level. If the detected magnetic flux surpasses a threshold level, the computer can direct an action to occur, such as lighting an LED, recording an entry in a log (e.g., recording the position of the hotpot on the tubular), marking the tubular (e.g., with ink), or any other suitable action. In some embodiments, the computer can perform some or all necessary tasks for automating the hotspot detection of the tubular.

While described with reference to tubulars (e.g., pressure casing), the hotspot detector and methods of use can be adjusted for use with any suitable material to be tested for magnetic hotspots.

These illustrative examples are given to introduce the reader to the general subject matter discussed here and are not intended to limit the scope of the disclosed concepts. The following sections describe various additional features and examples with reference to the drawings in which like numerals indicate like elements, and directional descriptions are used to describe the illustrative embodiments but, like the illustrative embodiments, should not be used to limit the present disclosure. The elements included in the illustrations herein may be drawn not to scale.

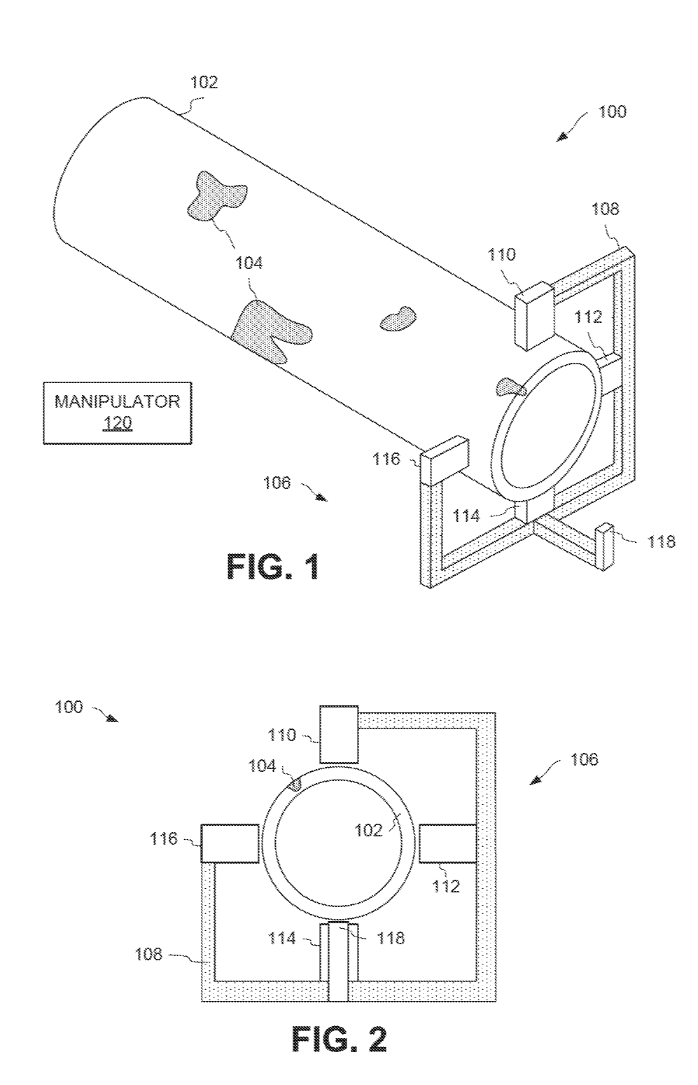

FIG. 1 is an axonometric projection of a hotspot detection system 100 according to certain features of the disclosed subject matter. The hotspot detection system 100 includes a sensor array 106 containing one or more sensors 110, 112, 114, 116. In some embodiments, more or fewer than four sensors 110, 112, 114, 116 are used. In some embodiments, the sensor array contains eight sensors in a single plane.

Each sensor can be a differential magnetic sensor, such as those described herein with regards to fluxgate magnetometers configured for differential magnetic sensing. In some embodiments, each sensor 110, 112, 114, 116 is a portion of a differential magnetic sensor. In one embodiment, sensors 110, 114 are each non-differential magnetic sensors coupled together in a configuration that creates a differential magnetic sensor, and sensors 112, 116 are each non-differential magnetic sensors coupled together in a configuration that creates a differential magnetic sensor, as described in further detail herein.

Multiple sensors 110, 112, 114, 116 can be supported by a jig 108 and positioned in a single plane to form a central aperture through which a tubular 102 can be placed. The systems and methods disclosed herein are described with regard to sensing hotspots in a tubular; however, the methods and systems described herein can be used to sense hotspots in other objects as well. Examples of objects include any object desired to be substantially non-magnetic, but which may present some magnetic dipoles.

The tubular 102 to be sensed may contain one or more magnetic hotspots 104. As described above, these hotspots 104 may include areas that are either actually magnetized or capable of being magnetized. While shown in FIGS. 1-4, hotpots 104, 304 may not be visually distinguishable to the naked eye.

The hotspot detection system 100 can allow the sensors 110, 112, 114, 116 to pass over the surface area of the tubular 102 at a relatively close distance. Because the sensors 110, 112, 114, 116 are differential magnetic sensors, the sensors 110, 112, 114, 116 do not register distant, ambient magnetic fields (because such fields would be homogenous in the vicinity of the sensors), but rather register localized (e.g., near the sensing portion of the sensor) magnetic fields, such as any magnetic hotspots 104 positioned adjacent the sensors 110, 112, 114, 116. In other words, ambient magnetic fields would register identically by each non-differential magnetic sensor in a differential magnetic sensor, and thus would cancel each other out in the differential magnetic sensor, however localized magnetic fields would be sensed differently by each of the non-differential magnetic sensors, thus resulting in an overall signal present in the differential magnetic sensor.

In some embodiments, the tubular 102 can be moved by a manipulator 120. The manipulator 120 can move the tubular 102 through the sensor array 106, thus allowing the sensors 110, 112, 114, 116 to scan the surface area of the tubular 102 as the tubular 102 moves through the sensor array 106. In some embodiments, the manipulator 120 can rotate the tubular 102, as well as move the tubular 102 in an axial direction. Rotation of the tubular 102 can allow portions of the tubular 102 which previously were not in-line with the sensors 110, 112, 114, 116 to be rotated to be in-line with the sensors 110, 112, 114, 116. In such an embodiment, after the tubular 102 has passed through the sensor array 106 a first time, the manipulator 120 can rotate the tubular 102 by a desired angle and pass the tubular 102 through the sensor array 106 a second time. This process can be repeated as many times as necessary to scan the tubular 102.

In some embodiments, the tubular 102 can remain still while a manipulator 120 moves the sensor array 106 to scan the tubular 102. The manipulator 120 can move the sensor array 106 axially along the length of the tubular 102, allowing the sensors 110, 112, 114, 116 to pass over and thus detect hotspots 104 in the tubular 102. In some embodiments, the manipulator 120 can also rotate the sensor array 106 to allow portions of the tubular 102 which were previously not in-line with the sensors 110, 112, 114, 116 to be in-line with the sensors 110, 112, 114, 116.

In some embodiments, the manipulator 120 can include portions that move the tubular 102 axially and rotate the sensor array 106. In some embodiments, the manipulator 120 can include portions that rotate the tubular 102 and move the sensor array 106 axially.

In some embodiments, the hotspot detection system 100 can include a marker 118. The marker 118 can be coupled to the rig 108 or separate from the rig 108. The marker 118 can mark the tubular 102 to indicate the presence of a hotspot 104. In some embodiments, the marker 118 marks the tubular 102 with ink at the location of the hotspot 104. In some embodiments, more than one marker 118 can be used. The marker 118 can be actuated by computer control or by an analog circuit. In some embodiments, the resultant mark is located at the hotpot 104, while in some embodiments the resultant mark is located at a known distance offset form the hotspot 104. While shown axially offset from sensor 114, the marker 118 may be positioned adjacent to a sensor 110, 112, 114, 116 or elsewhere.

FIG. 2 is a front view of the hotspot detection system 100 of FIG. 1 according to certain features of the disclosed subject matter. The hotspot detection system 100 includes a sensor array 106 that includes sensors 110, 112, 114, 116 supported by jig 108. The jig 108 additionally supports a marker 118. A tubular 102 having hotspots 104 can be positioned within the central aperture formed by the arrangement of sensors 110, 112, 114, 116.

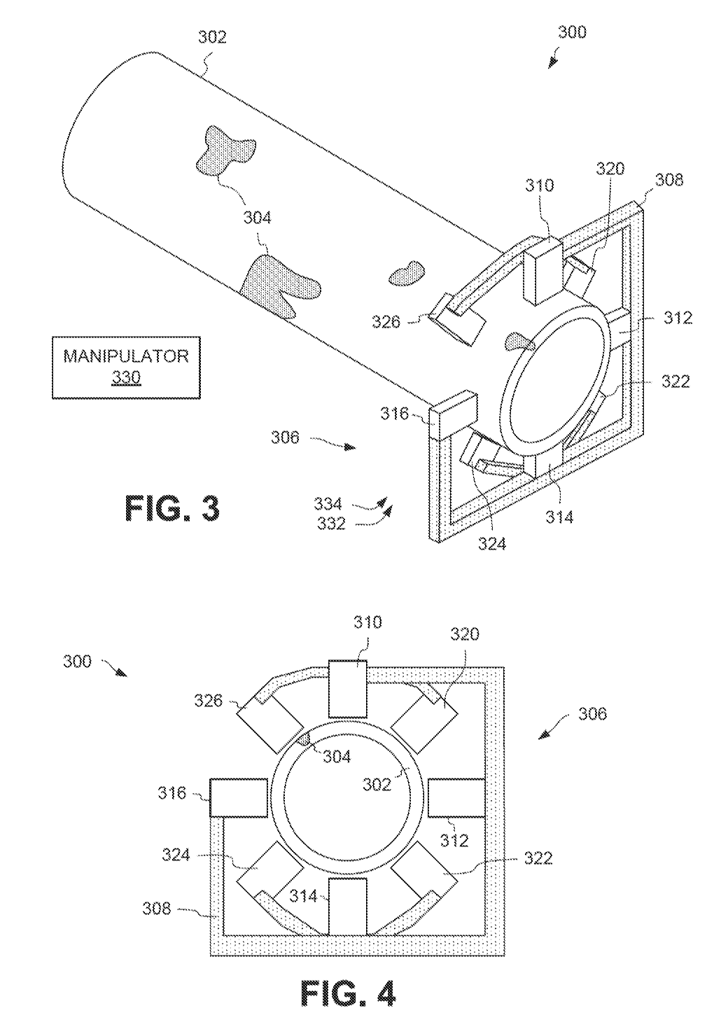

FIG. 3 is an axonometric projection of a hotspot detection system 300 with an offset set of sensors 326 according to certain features of the disclosed subject matter. The hotspot detection system 300 includes a sensor array 306 containing two sets of sensors 332, 334. The first set of sensors 332 includes sensors 310, 312, 314, 316. The second set of sensors 334 includes sensors 320, 322, 324, 326. The first set of sensors 332 is arranged in a plane axially offset from the second set of sensors 334. In some embodiments, each set of sensors 332, 334 can contain more or fewer than four sensors. In some embodiments, each set of sensors 332, 334 contains eight sensors. The sensors can be the same as the sensors described above with reference to FIGS. 1-2.

The first set of sensors 332 can be axially offset and rotationally offset from the sensors 320, 322, 324, 326 of the second set of sensors 334. Because of the offset positions of the first and second set of sensors 332, 334, more of the tubular 302 can be scanned with each pass through the sensor array 306. A single jig 308 can hold each set of sensors 332, 334. In some embodiments, each set of sensors 332, 334 is supported by its own jig.

The sensors 310, 312, 314, 316, 320, 322, 324, 326 can be arranged to form a central aperture through which tubular 302 can be placed. The first and second set of sensors 332, 334 can be located on axially offset, but parallel planes.

The hotspot detection system 300 can allow the sensors 310, 312, 314, 316, 320, 322, 324, 326 to pass over the surface area of the tubular 302 at a relatively close distance. Because the sensors 310, 312, 314, 316, 320, 322, 324, 326 are differential magnetic sensors, the sensors 310, 312, 314, 316, 320, 322, 324, 326 do not register distant, ambient magnetic fields, but rather register localized (e.g., near the sensing portion of the sensor) magnetic fields, such as any magnetic hotspots 304 positioned adjacent the sensor array 306.

As described above with reference to FIGS. 1-2, the tubular 302 can be moved by a manipulator 330, the sensor array 306 can be moved by a manipulator 330, or the manipulator 330 can move both the tubular 302 and the sensor array 306. In some embodiments, the first and second set of sensors 332, 334 can be moved by the manipulator 330 as a single unit. In some embodiments, the first and second set of sensors 332, 334 can be moved by the manipulator 330 individually.

When multiple sets of sensors 332, 334 are used, it may be unnecessary or less necessary for the tubular 302 to be rotated in order for the full tubular to be scanned by the sensor array 306.

FIG. 4 is a front view of the hotspot detection system 300 of FIG. 3 according to certain features of the disclosed subject matter. The hotspot detection system 300 includes a sensor array 306 that includes sensors 310, 312, 314, 316, 320, 322, 324, 326 supported by jig 308. A tubular 302 having hotspots 304 can be positioned within the central aperture formed by the arrangement of sensors 310, 312, 314, 316, 320, 322, 324, 326.

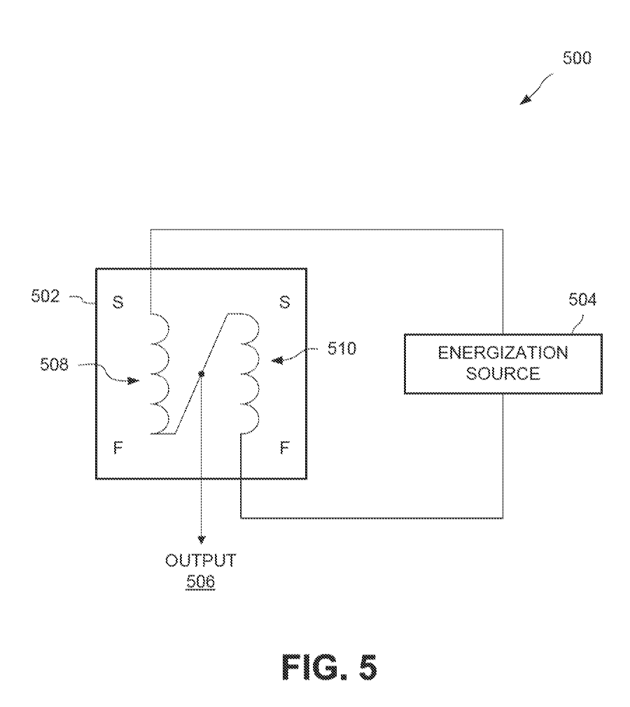

FIG. 5 is a schematic view of a differential fluxgate magnetometer 500 created from a single non-differential fluxgate magnetometer 502 according to certain features of the disclosed subject matter. The differential fluxgate magnetometer 500 can be created using a non-differential fluxgate magnetometer 502 configured as shown. The non-differential fluxgate magnetometer 502 can include a first coil 508 and a second coil 510, each having a start S and a finish F. Each coil can be a mu-metal rod wrapped in a coil. Other suitable coils with other suitable cores can be used. The finish F of the first coil 508 can be coupled to the start S of the second coil 510. An energization source 504 can be provided between the start S of the first coil 508 and the finish F of the second coil 510. The energization source 504 can be any suitable energization source, such as a center-tapped transformer that generates a square wave. Other suitable energization sources using other waves (e.g., a sine wave) could be used. The differential fluxgate magnetometer 500 can be measured at output 506, which is the connection between the finish F of the first coil 508 and the start S of the second coil 510.

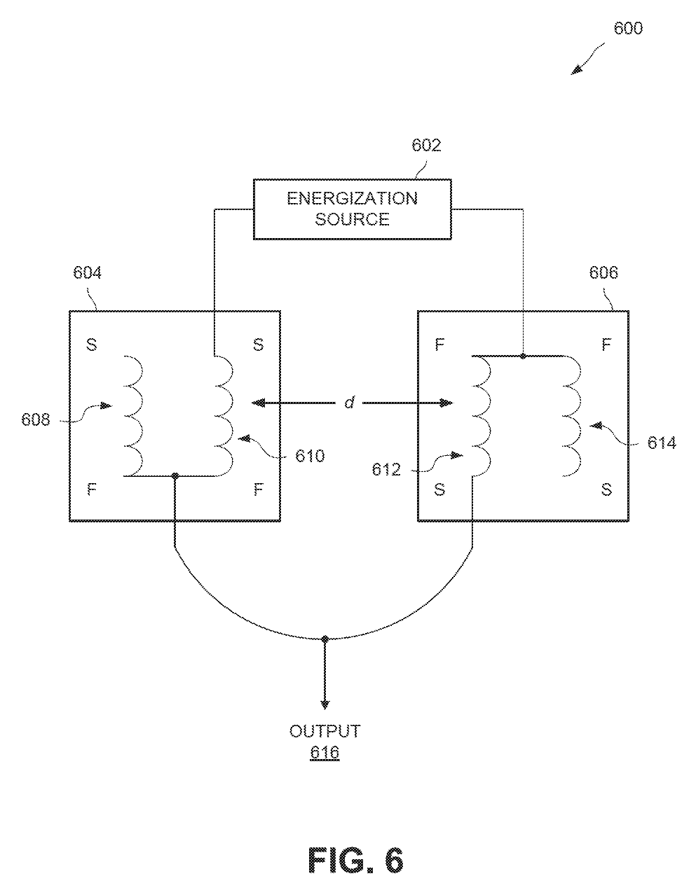

FIG. 6 is a schematic view of a differential fluxgate magnetometer 600 created from two non-differential fluxgate magnetometers 604, 606 arranged in a parallel arrangement according to certain features of the disclosed subject matter. The differential fluxgate magnetometer 600 can be created using a first non-differential fluxgate magnetometer 604 and a second non-differential fluxgate magnetometer 606 configured as shown.

The first non-differential fluxgate magnetometer 604 can include a first coil 608 and a second coil 610, each having a start S and a finish F. The second non-differential fluxgate magnetometer 606 can include a first coil 612 and a second coil 614, each having a start S and a finish F.

The finish F of the second coil 610 of the first non-differential fluxgate magnetometer 604 can be coupled to the start S of the first coil 612 of the second non-differential fluxgate magnetometer 606. An energization source 602 can be provided between the start S of the second coil 610 of the first non-differential fluxgate magnetometer 604 and the finish F of the first coil 612 of the second non-differential fluxgate magnetometer 606. The differential fluxgate magnetometer 600 can be measured at output 616, which is the connection between the finish F of the second coil 610 of the first non-differential fluxgate magnetometer 604 and the start S of the first coil 612 of the second non-differential fluxgate magnetometer 606.

The distance d is the distance between the second coil 610 of the first non-differential fluxgate magnetometer 604 and the first coil 612 of the second non-differential fluxgate magnetometer 606. If distance d is too large, any change in the gradient of the ambient magnetic field can be detected by the differential fluxgate magnetometer 600, which can be undesirable. If distance d is too small, the differential effect will be reduced.

The non-differential fluxgate magnetometers 604, 606 may be arranged parallel to each other.

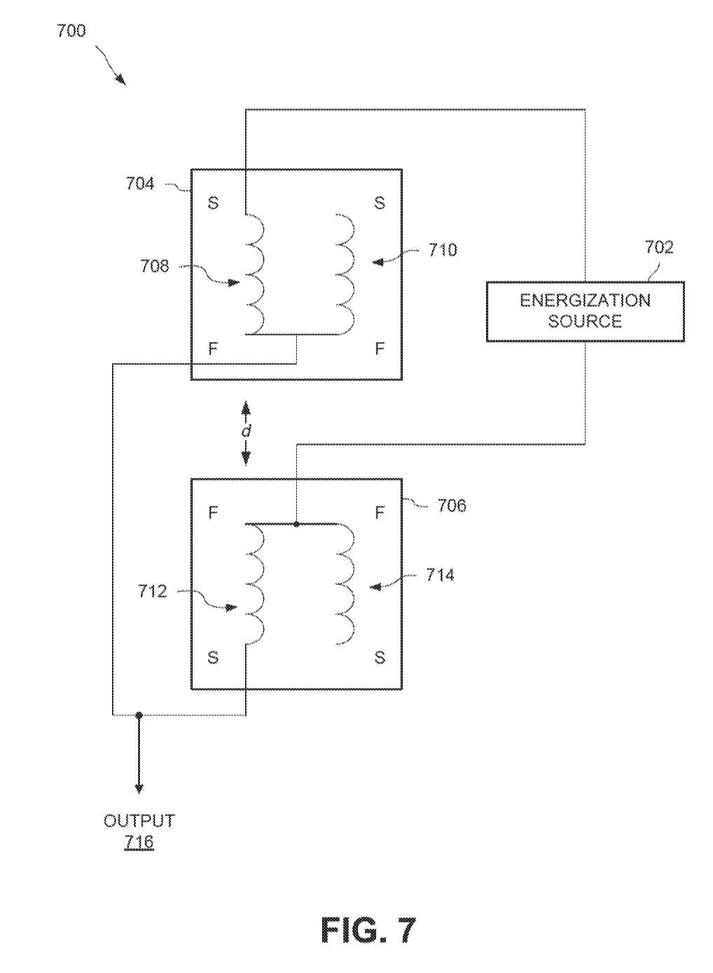

FIG. 7 is a schematic view of a differential fluxgate magnetometer 700 created from two non-differential fluxgate magnetometers 704, 706 arranged in a parallel and coincident arrangement according to certain features of the disclosed subject matter. The differential fluxgate magnetometer 700 can be created using a first non-differential fluxgate magnetometer 704 and a second non-differential fluxgate magnetometer 706 configured as shown.

The first non-differential fluxgate magnetometer 704 can include a first coil 708 and a second coil 710, each having a start S and a finish F. The second non-differential fluxgate magnetometer 706 can include a first coil 712 and a second coil 714, each having a start S and a finish F.

The finish F of the first coil 708 of the first non-differential fluxgate magnetometer 704 can be coupled to the start S of the first coil 712 of the second non-differential fluxgate magnetometer 706. An energization source 702 can be provided between the start S of the first coil 708 of the first non-differential fluxgate magnetometer 704 and the finish F of the first coil 712 of the second non-differential fluxgate magnetometer 706. The differential fluxgate magnetometer 700 can be measured at output 716, which is the connection between the finish F of the first coil 708 of the first non-differential fluxgate magnetometer 704 and the start S of the first coil 712 of the second non-differential fluxgate magnetometer 706.

The distance d is the distance between the first coil 708 of the first non-differential fluxgate magnetometer 704 and the first coil 712 of the second non-differential fluxgate magnetometer 706. The non-differential fluxgate magnetometers 704, 706 may be arranged parallel and coincident. If the non-differential fluxgate magnetometers 704, 706 are arranged in contact with one another (e.g., d is zero or near zero), the top and bottom ends (e.g., the ends with the starts S of the coils 708, 710, 712, 714) of the differential fluxgate magnetometer 700 can be positioned adjacent the object to be sensed. If distance d is a small distance, the middle ends (e.g., the ends with the finishes F of the coils 708, 710, 712, 714) of the differential fluxgate magnetometer 700 can be positioned adjacent the object to be sensed. In some embodiments, the non-differential fluxgate magnetometers 704, 706 are positioned sufficiently far apart to allow a tubular to be passed through them (e.g., through a central aperture formed between the non-differential fluxgate magnetometers 704, 706), thus allowing the tubular to be sensed by the differential fluxgate magnetometer 700.

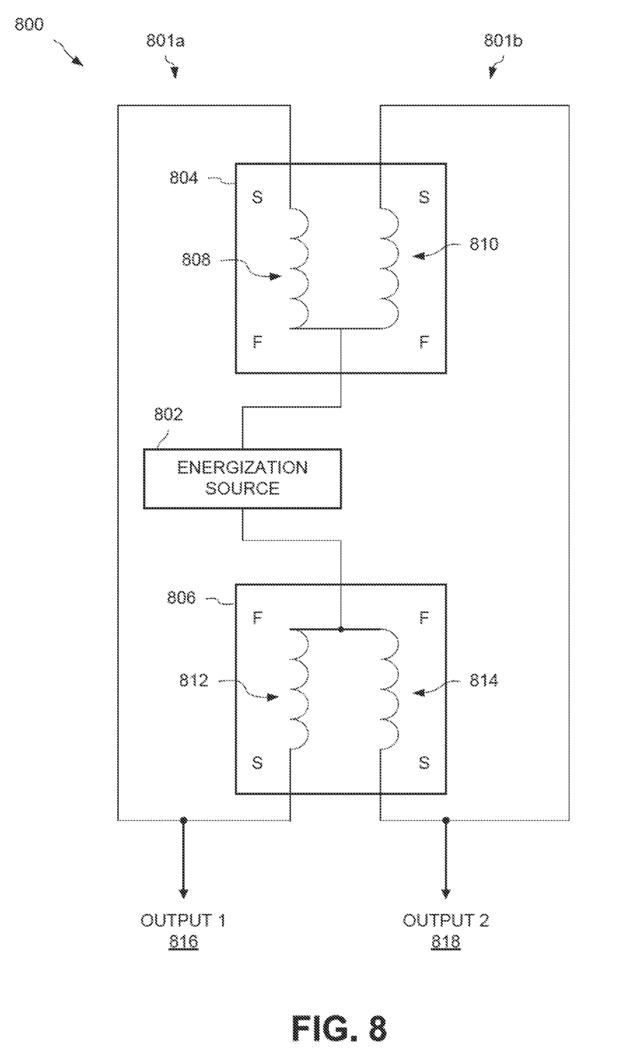

FIG. 8 is a schematic view of a set of differential fluxgate magnetometers 800 created from two non-differential fluxgate magnetometers 804, 806 arranged in a parallel and coincident arrangement according to certain features of the disclosed subject matter. First and second differential fluxgate magnetometers 801a, 801b can be created using a first non-differential fluxgate magnetometer 804 and a second non-differential fluxgate magnetometer 806 configured as shown.

The first non-differential fluxgate magnetometer 804 can include a first coil 808 and a second coil 810, each having a start S and a finish F. The second non-differential fluxgate magnetometer 806 can include a first coil 812 and a second coil 814, each having a start S and a finish F.

The start S of the first coil 808 of the first non-differential fluxgate magnetometer 804 can be coupled to the start S of the first coil 812 of the second non-differential fluxgate magnetometer 806. The start S of the second coil 810 of the first non-differential fluxgate magnetometer 804 can be coupled to the start S of the second coil 814 of the second non-differential fluxgate magnetometer 806. The finish F of the first coil 808 and second coil 810 of the first non-differential fluxgate magnetometer 804 can be coupled together. The finish F of the first coil 812 and second coil 814 of the second non-differential fluxgate magnetometer 806 can be coupled together. An energization source 802 can be provided between the finish F of the first and second coils 808, 810 of the first non-differential fluxgate magnetometer 804 and the finish F of the first and second coils 812, 814 of the second non-differential fluxgate magnetometer 806.

The first differential fluxgate magnetometer 801a can be measured at output 816, which is the connection between the start S of the first coil 808 of the first non-differential fluxgate magnetometer 804 and the start S of the first coil 812 of the second non-differential fluxgate magnetometer 806. The second differential fluxgate magnetometer 801b can be measured at output 818, which is the connection between the start S of the second coil 810 of the first non-differential fluxgate magnetometer 804 and the start S of the second coil 814 of the second non-differential fluxgate magnetometer 806.

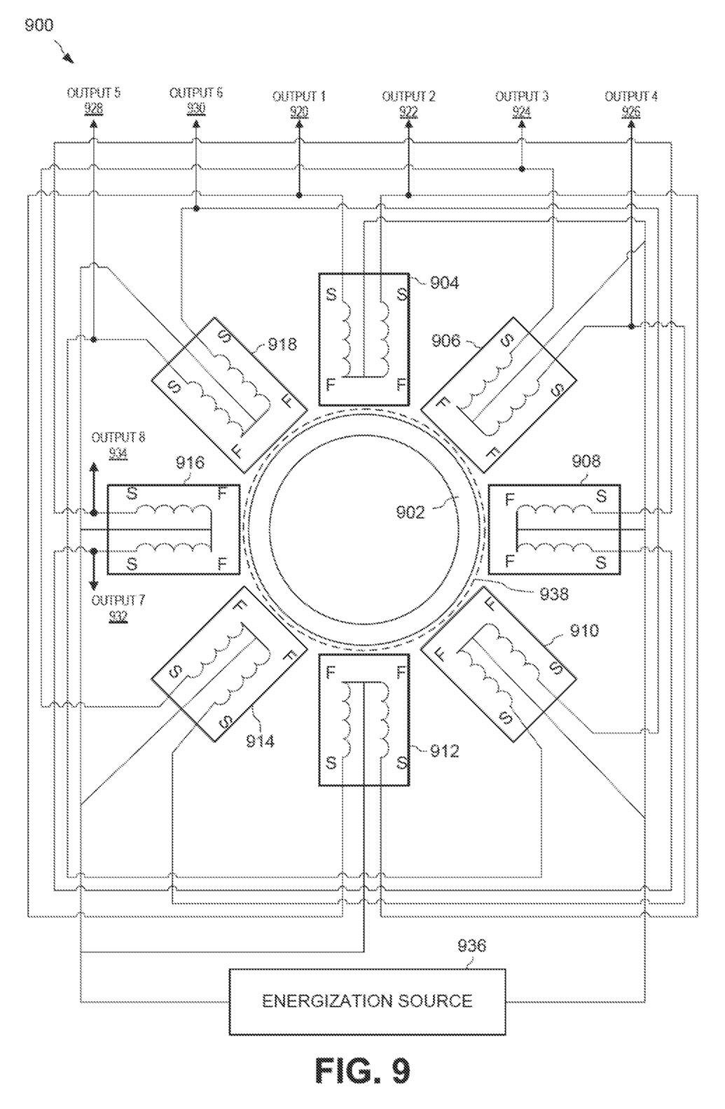

FIG. 9 is a schematic diagram depicting a sensor array 900 including four sets of differential fluxgate magnetometers created from eight non-differential fluxgate magnetometers 904, 906, 908, 910, 912, 914, 916, 918. Each set of differential fluxgate magnetometers can include two differential fluxgate magnetometers configured as described with reference to FIG. 8. Each differential fluxgate magnetometer can be measured by respective outputs 920, 922, 924, 926, 928, 930, 932, 934. An energization source 936 can energize each of the non-differential fluxgate magnetometers 904, 906, 908, 910, 912, 914, 916, 918. A tubular 902 can be moved through the central aperture 938 formed by the sensor array 900.

First and second differential fluxgate magnetometers can be created using first and second non-differential fluxgate magnetometers 904, 912 spaced on opposite sides of the central aperture 938 formed by the sensor array 900. Third and fourth differential fluxgate magnetometers can be created using third and fourth non-differential fluxgate magnetometers 906, 914 spaced on opposite sides of the central aperture 938 formed by the sensor array 900. Fifth and sixth differential fluxgate magnetometers can be created using fifth and sixth non-differential fluxgate magnetometers 908, 916 spaced on opposite sides of the central aperture 938 formed by the sensor array 900. Seventh and eighth differential fluxgate magnetometers can be created using seventh and eighth non-differential fluxgate magnetometers 910, 918 spaced on opposite sides of the central aperture 938 formed by the sensor array 900.

The use of eight differential fluxgate magnetometers results in a total of sixteen sensing locations (e.g., each finish F of each of the coils of the non-differential fluxgate magnetometers 904, 906, 908, 910, 912, 914, 916, 918).

In some embodiments, two sets of eight differential fluxgate magnetometers are used in axially offset planes, each set rotationally offset from the other by approximately 22.5°.

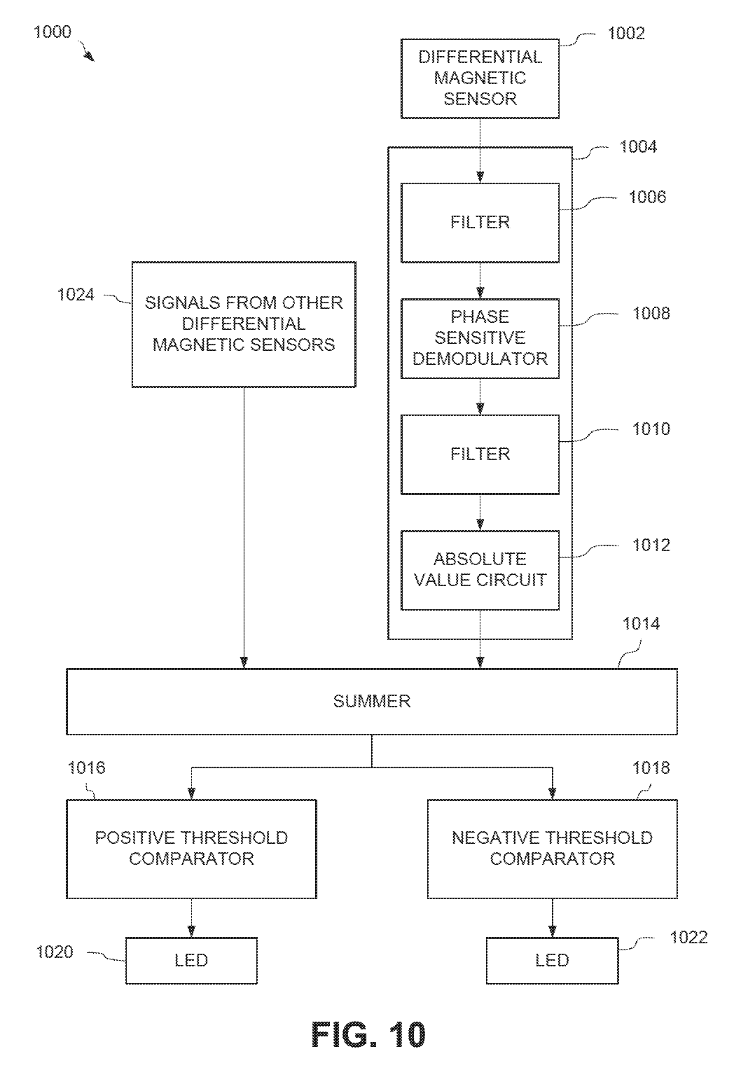

FIG. 10 is a block diagram of a system 1000 for analyzing signals from one or more differential magnetic sensors 1002. A signal from a differential magnetic sensor 1002 can be passed through a signal processing path 1004 before being passed to a summer 1014. The signal processing path 1004 can pass the signal from the differential magnetic sensor 1002 through a filter 1006, such as a low pass filter. The filtered signal can pass through a phase sensitive demodulator at block 1008. The demodulated signal can be passed through a second filter 1010, such as a low pass filter. The signal can pass through an absolute value circuit 1012.

The summer 1014 can accept signals from the differential magnetic sensor 1002. The summer 1014 can additional accept signals from one or more other differential magnetic sensors 1024. The signals from the one or more other differential magnetic sensors 1024 can all have passed through respective signal processing paths, including filters, demodulators, and absolute value circuits, as described above with reference to the signal from the differential magnetic sensor 1002. The summer can combine all received signals together. In some embodiments, the summer 1014 further includes a charge amplifier. The charge amplifier can make the scan speed less critical.

The output from the summer 1014 can be passed to both a positive threshold comparator 1016 and a negative threshold comparator 1018. If the output from the summer 1014 surpasses a threshold value, either positive or negative, the corresponding comparator 1016, 1018 will produce an indication. In some embodiments, the comparators 1016, 1018 can illuminate respective light-emitting diodes (LEDs) 1020, 1022.

As described with reference to FIG. 10, the comparators 1016, 1018 can determine whether the sensor array has detected a hotspot. In some embodiments, a summer 1014 is not used or each differential magnetic sensor is energized individually, in order for the hotspot detection system to be able to determine which sensor generated the signal. In other words, without a summer 1014, each differential magnetic sensor can be coupled to its own set of comparators to determine whether or not that particular magnetic sensor has sensed a hotpot.

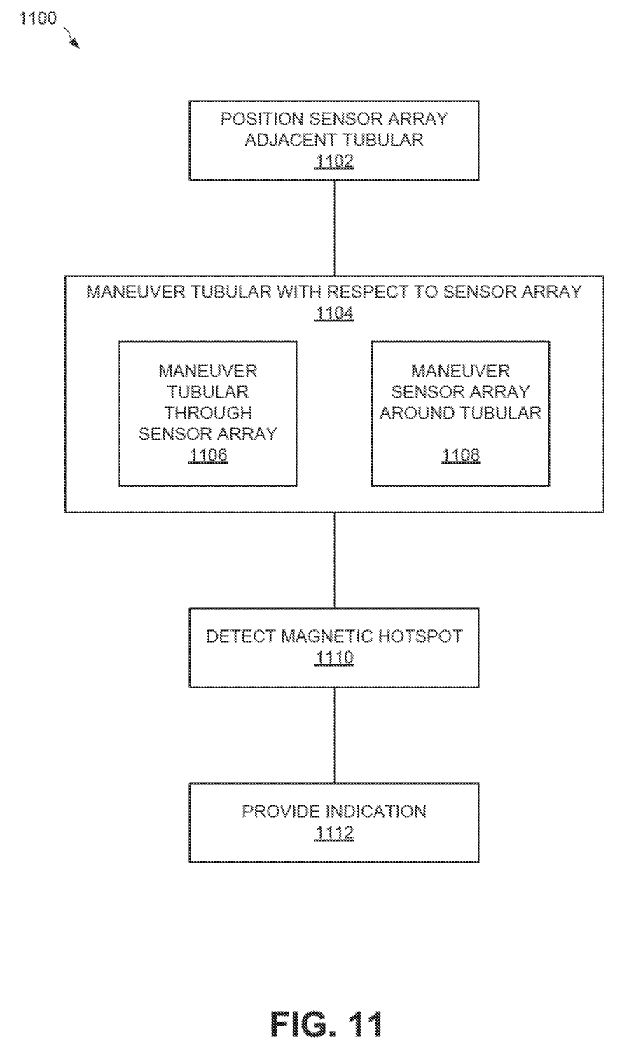

FIG. 11 is a flowchart of a process 1100 for detecting magnetic hotpots in a tubular according to certain features of the disclosed subject matter. At block 1102, a sensor array is positioned adjacent a tubular, which can include the sensor array being maneuvered adjacent the tubular or the tubular being maneuvered adjacent the sensor array.

At block 1104, the tubular is maneuvered with respect to the sensor array in order to allow the surface area of the tubular to pass within a sufficient distance (e.g., to sense a magnetic field) of sensors of the sensor array. Block 1104 can include one or more of maneuvering the tubular through the sensor array at block 1106 and maneuvering the sensor array around (e.g., axially) the tubular at block 1108. In some embodiments, at block 1104, the tubular or the sensor array can be rotated to allow additional surface area of the tubular to pass within a sufficient distance of sensors of the sensor array.

At block 1110, a magnetic hotspot can be detected. A magnetic hotspot can be detected when one or more differential fluxgate magnetometers detect a sufficiently large magnetic field change, indicative of a magnetic hotspot.

At block 1112, an indication can be provided. As described above, a comparator can determine when a sufficiently large magnetic field change is sensed by one or more sensors of the sensor array and can power an LED. In some embodiments, other indications can be provided. In some embodiments, the indication provided can include actuating a marker to mark the tubular at a location indicative of a hotspot in the tubular. In some embodiments, the indication includes other signals, such as creating an entry related to or describing the hotspot in a computer log.

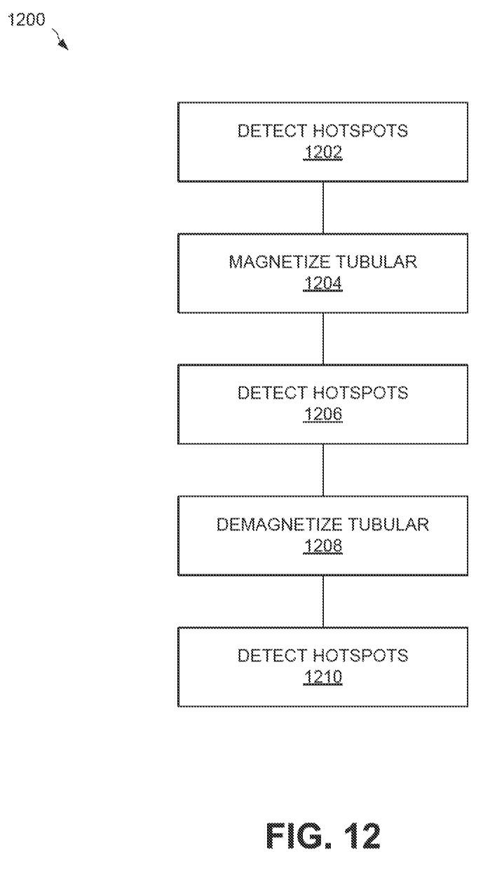

FIG. 12 is a flowchart of a process 1200 for detecting magnetic hotpots in a tubular according to certain features of the disclosed subject matter. At block 1202, magnetic hotspots can be detected in a tubular. At block 1202, hotpots that are already magnetized can be detected. At block 1204, the tubular can be magnetized in order to magnetize any latent hotspots of the tubular (e.g., hotspots that are not currently magnetized, but able to become magnetized). At block 1206, magnetic hotspots can be detected in the tubular a second time. At block 1206, all hotspots can be detected in the tubular. At block 1208, the tubular can be demagnetized. At block 1210, magnetic hotspots can be detected a third time.

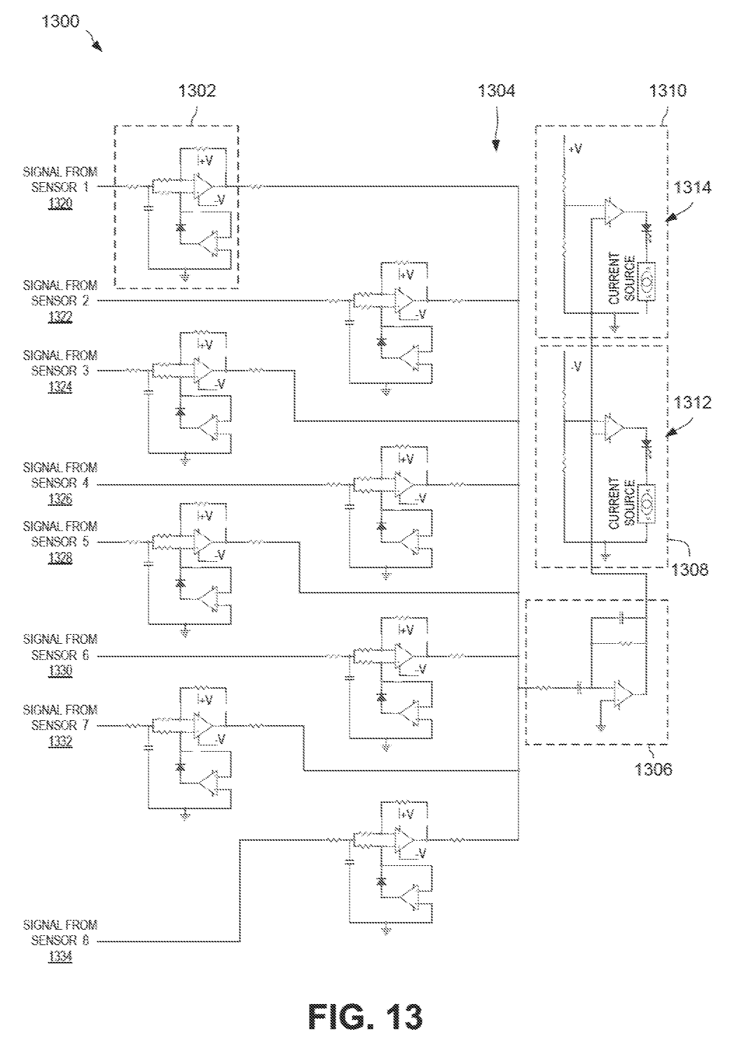

FIG. 13 is a schematic view of an indication circuit 1300 that includes signal processing paths 1302 for a hotspot detection system according to certain features of the disclosed subject matter. Suitable electronic hardware is depicted in the schematic diagram, although other electronic hardware, including similar hardware with different values (e.g., values of resistance) can be used.

The indication circuit 1300 can accept and process signals from eight sensors 1320, 1322, 1324, 1326, 1328, 1330, 1332, 1334. The signals from each sensor can pass through individual signal processing paths 1302. A signal processing path 1302 can include elements such as filters, phase sensitive demodulators, and absolute value circuits.

The signals from the signal processing paths 1302 can pass through a summer 1304 that combines the signals. In some embodiments, the summer can include a number of resistors, each connected to a respective signal processing path 1302 on their first ends and each connected together on their second ends. The summer 1304 can include a charge amplifier 1306. In some embodiments, the output of the charge amplifier 1306 or summer 1304 can pass to a first and second comparator 1308, 1310. The comparators can drive LEDs 1312, 1314.

In some embodiments, the signals from the differential fluxgate magnetometers, before or after being processed, can be passed to a computer for further processing, such as to compare the sensed signal with a threshold value.

The foregoing description of the embodiments, including illustrated embodiments, has been presented only for the purpose of illustration and description and is not intended to be exhaustive or limiting to the precise forms disclosed. Numerous modifications, adaptations, and uses thereof will be apparent to those skilled in the art.

As used below, any reference to a series of examples is to be understood as a reference to each of those examples disjunctively (e.g., “Examples 1-4” is to be understood as “Examples 1, 2, 3, or 4”).

Example 1 is a method including performing hotspot detection of a tubular including positioning a sensor array adjacent the tubular, the sensor array comprising at least one differential magnetic sensor; detecting a magnetic hotspot of the tubular by the sensor array; and providing an indication in response to detecting the magnetic hotspot.

Example 2 is the method of example 1 where performing hotspot detection further includes maneuvering the tubular with respect to the sensor array, wherein the sensor array comprises a plurality of differential magnetic sensors circularly arranged to form an aperture sized to accept the tubular, and wherein maneuvering the tubular includes passing the tubular through the aperture.

Example 3 is the method of example 2 where maneuvering the tubular further includes rotating the tubular with respect to the sensor array and passing the tubular through the aperture a second time.

Example 4 is the method of examples 2 or 3 where the sensor array further includes a second plurality of differential magnetic sensors rotationally and axially offset from the plurality of differential magnetic sensors. The second plurality of differential magnetic sensors are circularly arranged to form a second aperture that is sized to accept the tubular and that is coaxial with the aperture. In Example 4, maneuvering the tubular includes passing the tubular through the second aperture.

Example 5 is the method of examples 1-4 where performing hotspot detection further includes maneuvering the tubular with respect to the sensor array, wherein the sensor array passes adjacent substantially all of an outer surface of the tubular during maneuvering the tubular.

Example 6 is the method of examples 1-5 further including demagnetizing the tubular.

Example 7 is the method of examples 1-6 further including magnetizing latent hotspots of the tubular.

Example 8 is the method of examples 1-7 where providing the indication includes marking the tubular with a mark indicative of a location of the magnetic hotspot.

Example 9 is a system including a sensor array that includes a plurality of differential fluxgate sensors forming a central aperture sized to accept a tubular; at least one energization source coupled to the sensor array for energizing the plurality of differential fluxgate sensors; and an indication circuit coupled to the sensor array for providing an indication in response to a magnetic hotspot being detected by the sensor array.

Example 10 is the system of example 9 also including a manipulator for moving the tubular with respect to the sensor array.

Example 11 is the system of example 10 where the manipulator includes a rotational actuator for rotating the tubular with respect to the sensor array.

Example 12 is the system of examples 9-11 where the sensor array further includes a second plurality of differential fluxgate sensors rotationally and axially offset from the plurality of differential fluxgate sensors, the second plurality of differential fluxgate sensors forming a second aperture sized to accept the tubular and coaxial with the central aperture, and wherein the at least one energization source is coupled to the sensor array for energizing the second plurality of differential fluxgate sensors.

Example 13 is the system of examples 9-12 where the indication circuit includes a plurality of low-pass filters for receiving raw signals from each of the plurality of differential fluxgate sensors; a plurality of absolute value circuits for receiving filtered signals from the plurality of low-pass filters and outputting a plurality of absolute value signals; a summer circuit for combining the plurality of absolute value signals into a combined signal; and at least one comparator for comparing the combined signal to a threshold value, wherein the comparator provides the indication when the combined signal exceeds the threshold value.

Example 14 is the system of examples 9-13 where each of the plurality of differential fluxgate sensors includes a pair of non-differential fluxgate sensors.

Example 15 is the system of example 14 where one of the pair of non-differential fluxgate sensors is positioned opposite a center of the central aperture from the other of the pair of non-differential fluxgate sensors.

Example 16 is a system including a sensor array that includes a plurality of differential magnetic sensors forming an aperture sized to accept a tubular; an indication circuit coupled to the sensor array for providing an indication in response to a magnetic hotspot being detected by the sensor array; and a manipulator for moving the tubular with respect to the sensor array.

Example 17 is the system of example 16 where the sensor array further includes a second plurality of differential magnetic sensors rotationally and axially offset from the plurality of differential magnetic sensors, the second plurality of differential magnetic sensors forming a second aperture sized to accept the tubular and coaxial with the aperture.

Example 18 is the system of example 17 further including a plurality of low-pass filters for receiving raw signals from each of the plurality of differential magnetic sensors; a plurality of absolute value circuits for receiving filtered signals from the plurality of low-pass filters and outputting a plurality of absolute value signals; a summer circuit for combining the plurality of absolute value signals into a combined signal; and at least one comparator for comparing the combined signal to a threshold value, wherein the comparator provides an indication when the combined signal exceeds the threshold value.

Example 19 is the system of examples 16-19 where each of the plurality of differential magnetic sensors includes a pair of non-differential magnetic sensors.

Example 20 is the system of example 19 where one of the pair of non-differential magnetic sensors is positioned opposite a center of the aperture from the other of the pair of non-differential magnetic sensors.

What is claimed is:

1. A method, comprising:
positioning a sensor array adjacent the tubular, the sensor array comprising at least one differential magnetic sensor;
detecting a magnetic hotspot of the tubular by the sensor array; and
providing an indication in response to detecting the magnetic hotspot to perform hotspot detection of the tubular.

2. The method of claim 1, further comprising:
maneuvering the tubular with respect to the sensor array, wherein the sensor array comprises a plurality of differential magnetic sensors circularly arranged to form an aperture sized to accept the tubular, and wherein maneuvering the tubular includes passing the tubular at least partially through the aperture.

3. The method of claim 2, wherein maneuvering the tubular further comprises rotating the tubular with respect to the sensor array and passing the tubular through the aperture a second time.

4. The method of claim 2, wherein the sensor array further comprises a second plurality of differential magnetic sensors rotationally and axially offset from the plurality of differential magnetic sensors, the second plurality of differential magnetic sensors being circularly arranged to form a second aperture sized to accept the tubular and coaxial with the aperture, and wherein maneuvering the tubular includes passing the tubular through the second aperture.

5. The method of claim 1, further comprising:
maneuvering the tubular with respect to the sensor array, wherein the sensor array passes adjacent substantially all of an outer surface of the tubular during maneuvering of the tubular.

6. The method of claim 1, further comprising:
demagnetizing the tubular.

7. The method of claim 6, further comprising:
magnetizing latent hotspots of the tubular.

8. The method of claim 1, wherein providing the indication includes marking the tubular with a mark indicative of a location of the magnetic hotspot.

9. A system, comprising:
a sensor array including a plurality of differential fluxgate sensors forming a central aperture sized to accept a tubular;
at least one energization source coupled to the sensor array for energizing the plurality of differential fluxgate sensors; and
an indication circuit coupled to the sensor array for providing an indication in response to a magnetic hotspot being detected by the sensor array.

10. The system of claim 9, further comprising:
a manipulator for moving the tubular with respect to the sensor array.

11. The system of claim 10, wherein the manipulator comprises a rotational actuator for rotating the tubular with respect to the sensor array.

12. The system of claim 9, wherein the sensor array further comprises a second plurality of differential fluxgate sensors rotationally and axially offset from the plurality of differential fluxgate sensors, the second plurality of differential fluxgate sensors forming a second aperture sized to accept the tubular and coaxial with the central aperture, and wherein the at least one energization source is coupled to the sensor array for energizing the second plurality of differential fluxgate sensors.

13. The system of claim 9, wherein the indication circuit comprises:
a plurality of low-pass filters for receiving raw signals from each of the plurality of differential fluxgate sensors;
a plurality of absolute value circuits for receiving filtered signals from the plurality of low-pass filters and outputting a plurality of absolute value signals;
a summer circuit for combining the plurality of absolute value signals into a combined signal; and
at least one comparator for comparing the combined signal to a threshold value, wherein each of the at least one comparator provides the indication when the combined signal exceeds the threshold value.

14. The system of claim 9, wherein each of the plurality of differential fluxgate sensors includes a pair of non-differential fluxgate sensors.

15. The system of claim 14, wherein one of the pair of non-differential fluxgate sensors is positioned opposite a center of the central aperture from the other of the pair of non-differential fluxgate sensors.

16. A system, comprising:
a sensor array including a plurality of differential magnetic sensors forming an aperture sized to accept a tubular;
an indication circuit coupled to the sensor array for providing an indication in response to a magnetic hotspot being detected by the sensor array; and
a manipulator for moving the tubular with respect to the sensor array.

17. The system of claim 16, wherein the sensor array further comprises a second plurality of differential magnetic sensors rotationally and axially offset from the plurality of differential magnetic sensors, the second plurality of differential magnetic sensors forming a second aperture sized to accept the tubular and coaxial with the aperture.

18. The system of claim 17, further comprising:
a plurality of low-pass filters for receiving raw signals from each of the plurality of differential magnetic sensors;
a plurality of absolute value circuits for receiving filtered signals from the plurality of low-pass filters and outputting a plurality of absolute value signals;
a summer circuit for combining the plurality of absolute value signals into a combined signal; and
at least one comparator for comparing the combined signal to a threshold value, wherein each of the at least one comparator provides the indication when the combined signal exceeds the threshold value.

19. The system of claim 17, wherein each of the plurality of differential magnetic sensors includes a pair of non-differential magnetic sensors.

20. The system of claim 19, wherein one of the pair of non-differential magnetic sensors is positioned opposite a center of the aperture from the other of the pair of non-differential magnetic sensors.
